(19) United States
(12) Patent Application Publication
(10) Pub. No.: US 2024/0397707 A1
(43) Pub. Date: Nov. 28, 2024

(54) SEMICONDUCTOR MEMORY DEVICE AND MANUFACTURING METHOD THEREOF

(71) Applicant: SAMSUNG ELECTRONICS CO., LTD., Suwon-si (KR)

(72) Inventors: Sangkyu SUN, Suwon-si (KR); Goro CHOI, Suwon-si (KR); Hyo-Sub KIM, Suwon-si (KR); Junhyeok AHN, Suwon-si (KR); Eunkyung CHA, Suwon-si (KR); Dongmin CHOI, Suwon-si (KR); Sanghyun CHOI, Suwon-si (KR)

(21) Appl. No.: 18/381,785

(22) Filed: Oct. 19, 2023

(30) Foreign Application Priority Data
May 25, 2023 (KR) 10-2023-0067545

(51) Int. Cl. H10B 12/00; H01L 29/423

(52) U.S. Cl. CPC H10B 12/485; H01L 29/42356; H10B 12/02; H10B 12/482; H10B 12/488

(57) ABSTRACT

A semiconductor memory device includes a substrate having a cell array area and a core area near the cell array area, the cell array area including a direct contact hole exposing an active region, a buried contact in the cell array area, the buried contact being connected to a storage element, a direct contact in the cell array area, the direct contact including an upper layer and a lower layer, the upper layer including a metal, and the lower layer being in the direct contact hole in direct contact with the active region and including a silicide of the metal, bit lines in contact with the upper layer of the direct contact, and word lines crossing the bit lines.

### CROSS-REFERENCE TO RELATED APPLICATION

This application claims priority to and the benefit of Korean Patent Application No. 10-2023-0067545 filed in the Korean Intellectual Property Office on May 25, 2023, the entire contents of which are incorporated herein by reference.

### BACKGROUND

### 1. Field

The present disclosure relates to a semiconductor device and a manufacturing method thereof, and more particularly, to a semiconductor memory device and a manufacturing method thereof.

### 2. Description of the Related Art

As a degree of integration of semiconductor memory devices increases, circuits are becoming finer, thereby decreasing design rules. Thus, manufacturing processes of the semiconductor memory devices become more complicated and difficult.

### SUMMARY

An embodiment of the present disclosure provides a semiconductor memory device including a substrate having a cell array area and a core area near the cell array area, a buried contact located in the cell array area and connected to a storage element, a direct contact located in the cell array area and including an upper layer and a lower layer, bit lines in contact with the upper layer of the direct contact, and word lines crossing the bit lines, in which the lower layer of the direct contact is located in a direct contact hole of the substrate exposing an active region of the substrate, the lower layer is in contact with the active region of the substrate through a bottom surface of the direct contact hole, the upper layer includes a metal, and the lower layer includes a silicide of the metal.

An embodiment of the present disclosure provides a manufacturing method of a semiconductor memory device, the manufacturing method including forming a direct contact hole by stacking a cell insulating film on a cell array area of a substrate and etching the cell insulating film, the direct contact hole exposing an active region of the substrate, forming a lower layer on the exposed active region and in the direct contact hole, the lower layer including a semiconductor. forming an upper layer on the lower layer, the upper layer including a metal. converting at least a portion of the lower layer into a silicide of the metal, forming bit lines on the upper layer, and forming a direct contact by etching the upper layer and the lower layer by using the bit lines as a mask.

### BRIEF DESCRIPTION OF THE DRAWINGS

Features will become apparent to those of skill in the art by describing in detail exemplary embodiments with reference to the attached drawings, in which:

FIG. 1 is a partial plan view of a cell array area of a semiconductor device according to an embodiment of the present disclosure.

FIGS. 2 to 5 are cross-sectional views taken along lines A-A, B-B, C-C, and D-D of FIG. 1, respectively.

FIGS. 6 to 10 are cross-sectional views of stages in a manufacturing process of the semiconductor device of FIG. 2.

### DETAILED DESCRIPTION

In the following detailed description, only certain exemplary embodiments of the present disclosure have been shown and described, simply by way of illustration. As those skilled in the art would realize, the described embodiments may be modified in various different ways, all without departing from the spirit or scope of the present disclosure. Accordingly, the drawings and description are to be regarded as illustrative in nature and not restrictive. Like reference numerals designate like elements throughout the specification.

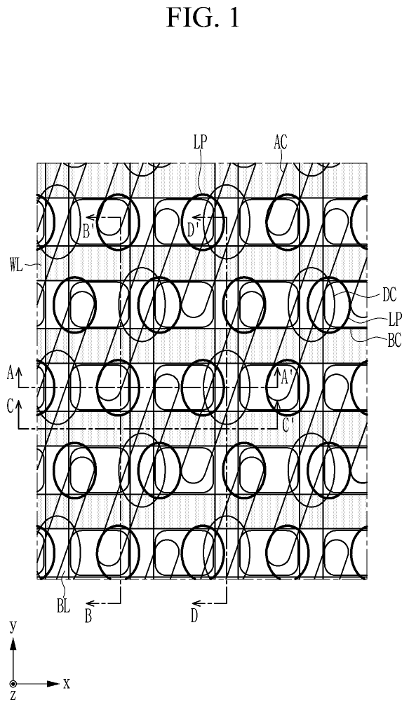

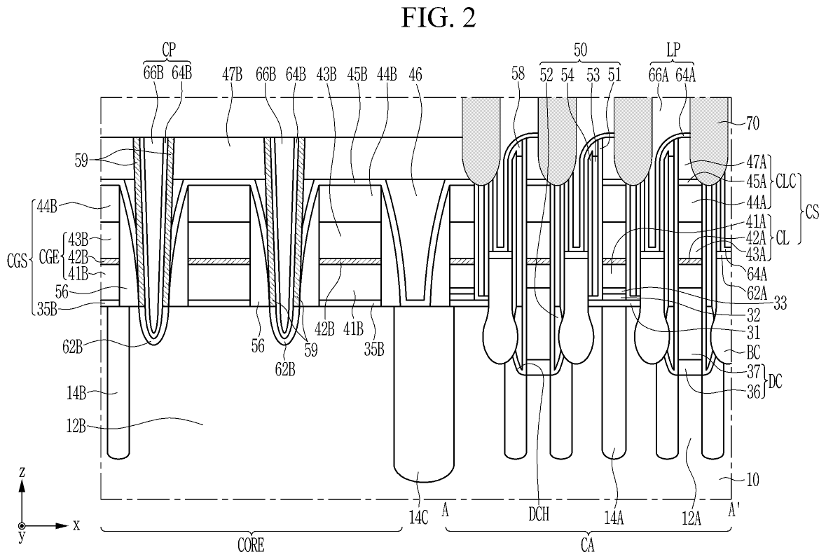

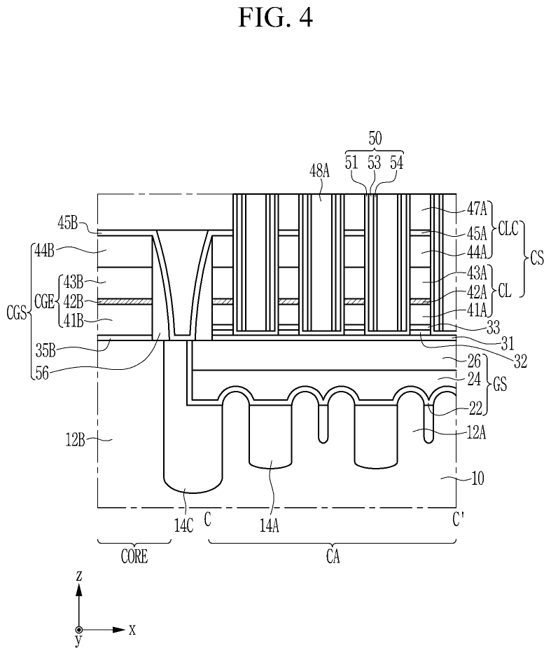

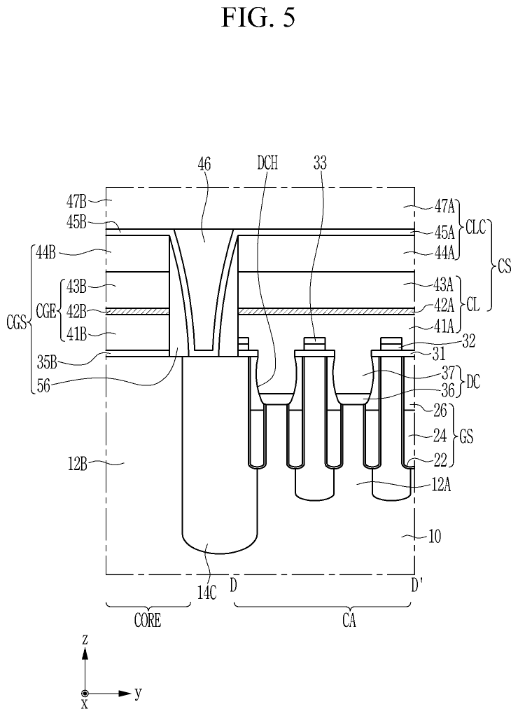

FIG. 1 is a diagram illustrating a partial structure of a cell array area CA of a semiconductor device according to an embodiment of the present disclosure. FIGS. 2 to 5 are cross-sectional views taken along lines A-A, B-B, C-C, and D-D of FIG. 1, respectively. FIGS. 2, 4, and 5 illustrate a portion of the core area CORE, in addition to the cell array area CA. While the drawings illustrate a dynamic random access memory (DRAM), example embodiments may be implemented in any suitable semiconductor device.

Referring to FIG. 1, the semiconductor device according to an embodiment of the present disclosure may include the cell array area CA and a core area CORE. The core area CORE may be located near, e.g., adjacent, the cell array area CA.

The cell array area CA may include a plurality of active regions AC. The active regions AC may be defined by an isolation layer 14A of FIG. 2 formed in a substrate 10 of FIG. 2. As a design rule of the semiconductor device decreases, the active regions AC may be provided in the form of a diagonal or an oblique line bar (e.g., relative to a direction of a word line WL), as shown in FIG. 1.

A plurality of word lines WL may cross the active regions AC to form a plurality of gate electrodes. The plurality of word lines WL may extend in, e.g., a first direction (an x-axis direction), to be parallel to each other, and may be arranged at uniform intervals. A width of each of the word lines WL or a gap between adjacent ones of the word lines WL may be determined according to a design rule.

Each of the active regions AC may cross two word lines WL, thus being divided into three parts, in which an intermediate part may be a bit line connection region and the end parts may be storage element connection regions. Because the active regions AC extend in a diagonal direction, an angle formed by the word lines WL and the active regions AC may be less than 90°.

A plurality of bit lines BL may cross the word lines WL, and may be, e.g., orthogonal to the word lines WL. The plurality of bit lines BL may each extend in, e.g., a second direction (a y-axis direction), and may be positioned on the word lines WL. The plurality of bit lines BL may be disposed at uniform intervals to be parallel to each other. A width of the bit lines BL or a gap between the bit lines BL may be determined according to the design rule.

The semiconductor device according to the embodiment of the present disclosure may include various types of contact structures on the active regions AC. For example, as illustrated in FIG. 1, the semiconductor device according to example embodiments may include a direct contact DC, a buried contact BC, a landing pad LP, and the like.

The direct contact DC may be a contact structure that electrically connects the active region AC to the bit lines BL. The buried contact BC may be a contact structure that connects the active region AC to a lower electrode of a capacitor.

In an arrangement structure of the buried contact BC, a contact area between the buried contact BC and the active region AC may be small, and a conductive landing pad LP may be employed between the active region AC and the buried contact BC to increase the contact area. Alternatively, the landing pad LP may be interposed between the buried contact BC and the lower electrode of the capacitor to increase a contact area between the lower electrode of the capacitor and the buried contact BC. Contact resistance between the active region AC and the lower electrode of the capacitor may be reduced by increasing the contact area through the landing pad LP.

The direct contact DC may be connected to a bit line connection region of the active region AC, and the buried contact BC may be connected to a storage element connection region. Therefore, the landing pad LP may be adjacent to or partially (or entirely) overlap the buried contact BC of the active region AC. In other words, the buried contact BC may be formed to overlap the active region AC and the isolation layer 14A between adjacent word lines WL and between adjacent bit lines BL.

A plurality of buried contacts BC may be arranged to be spaced apart from each other in the first direction (the x-axis direction) and the second direction (the y-axis direction).

In an embodiment of the present disclosure, the word lines WL may be buried in the substrate 10. The word line WL may be arranged across the active region AC between direct contacts DC or between buried contacts BC.

The direct contacts DC may be arranged symmetrically and thus disposed in a line in the first direction (the x-axis direction) and the second direction (the y-axis direction). The buried contacts BC may also be arranged symmetrically and thus disposed in a line in the first direction (the x-axis direction) and the second direction (the y-axis direction). However, unlike direct contacts DC and the buried contacts BC, the landing pads LP may be arranged in a zigzag form in the second direction (the y-axis direction) in which the bit lines BL extend. Alternatively, the landing pads LP may be arranged to overlap the same sides of the bit lines BL in the first direction (the x-axis direction) in which the word lines WL extend. For example, the landing pads LPs in a first column may overlap the left sides of the bit lines BL corresponding thereto, and the landing pads LPs in a second column may overlap the right sides of the corresponding bit lines BL.

Referring to FIGS. 2 to 5, a semiconductor device according to an embodiment of the present disclosure includes the substrate 10.

The substrate 10 may include the cell array area CA and the core area CORE separated from each other by a cell area separation layer 14C. The cell array area CA and the core area CORE may respectively include an active region 12A and an active region 12B that are defined by isolation layers 14A and 14B, respectively. That is, because the active regions 12A and 12B are defined by the isolation layers 14A and 14B, the isolation layers 14A and 14B are arranged around the active regions 12A and 12B.

In the cell array area CA, the plurality of active regions 12A may each have a relatively long island shape with a short axis and a long axis, as seen in a top view in FIG. 1. The active regions 12A in FIGS. 2-5 correspond to the active regions AC in FIG. 1.

For example, the substrate 10 may be a silicon substrate or a silicon-on-insulator (SOI). In another example, the substrate 10 may include silicon germanium, a silicon-germanium-on insulator (SGOI), indium antimonide, lead telluride, indium arsenide, indium phosphide, gallium arsenide, or gallium antimonide.

The isolation layers 14A and 14B and the cell area separation layer 14C may have a shallow trench isolation (STI) structure with excellent isolation characteristics. The isolation layers 14A and 14B and the cell area separation layer 14C may include silicon oxide, silicon nitride, silicon oxynitride, or a combination thereof. For example, as illustrated in FIGS. 2 to 5, the isolation layers 14A and 14B and the cell area separation layer 14C may be single layers. In another example, the isolation layers 14A and 14B and the cell area separation layer 14C may be formed as one insulating layer or multiple insulating layers according to the widths thereof. For example, as illustrated in FIGS. 2 to 5, upper surfaces of the isolation layers 14A and 14B and an upper surface of the cell area separation layer 14C may be level with an upper surface of the substrate 10.

A semiconductor device according to an embodiment of the present disclosure may include word lines having a buried structure in the cell array area CA. In an embodiment of the present disclosure, a cell gate structure GS including a structure corresponding to word lines may be formed in the substrate 10 and the isolation layer 14A.

The cell gate structure GS may cross the isolation layer 14A and the active region 12A defined by the isolation layer 14A. The cell gate structure GS may include a cell gate insulating layer 22, a cell gate electrode 24, and a cell gate capping 26. Here, the cell gate electrode 24 may correspond to the word line WL in FIG. 1. For example, the cell gate structure GS may further include a cell gate capping conductive layer.

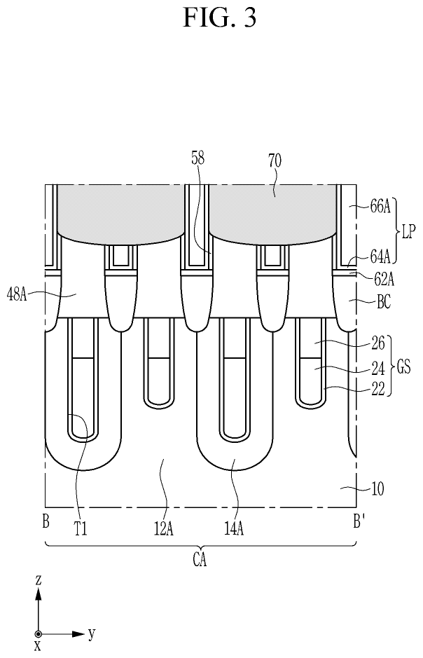

Referring to FIG. 3, the cell gate insulating layer 22 may be formed along side walls and a bottom surface of a cell gate trench T1 according to a profile of at least a portion of the cell gate trench T1. The cell gate insulating layer 22 may include, e.g., at least one of silicon oxide, silicon nitride, silicon oxynitride, or a high-k material having a dielectric constant higher than that of silicon oxide. The high-K material may include, e.g., at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or a combination thereof.

The cell gate electrode 24 may be formed on the cell gate insulating layer 22. The cell gate electrode 24 may fill a part of the cell gate trench T1. When a cell gate capping conductive layer is provided, the cell gate capping conductive layer may extend along an upper surface of the cell gate electrode 24.

The cell gate electrode 24 may include, e.g., at least one of a metal, a metal alloy, a conductive metal nitride, a conductive metal carbonitride, a conductive metal carbide, a metal silicide, a doped semiconductor material, a conductive metal oxynitride, and a conductive metal oxide. The cell gate electrode 24 may include, e.g., at least one of TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOₓ, RuOₓ, or a combination thereof. The cell gate capping conductive layer may include, e.g., polysilicon or polysilicon-germanium.

The cell gate capping 26 may be provided on the cell gate electrode 24 (or the cell gate capping conductive layer). The cell gate capping 26 may fill a remaining space of the cell gate trench T1 that is not occupied by the cell gate electrode 24. For example, as illustrated in FIG. 3, the cell gate insulating layer 22 may be formed along the sidewalls of the cell gate capping 26. The cell gate capping 26 may include, e.g., at least one of silicon nitride (SiN), silicon oxynitride (SiON), silicon oxide (SiO₂), silicon carbonitride (SiCN), silicon oxycarbonitride (SiOCN), or a combination thereof.

For example, an impurity-containing region into which impurities are injected may be provided on at least one side of the cell gate structure GS. The impurity-containing region may be a source/drain region of a transistor.

As illustrated in FIG. 2, a cell conductive line CL corresponding to the bit line BL in FIG. 1 may be provided in the cell array area CA, and a cell line capping layer CLC may be provided on the cell conductive line CL. In the present specification, the cell conductive line CL and the cell line capping layer CLC will be referred to together as a “cell line structure CS”. In an embodiment of the present disclosure, the cell line structure CS may be located on the substrate 10, and may cross the isolation layer 14A and the active region AC. The cell line structure CS may also cross the cell gate structure GS, and may extend, e.g., in the second direction (the y-axis direction).

The cell conductive line CL may be a multi-layer. For example, as illustrated in FIG. 2, the cell conductive line CL may include, e.g., a lower conductive layer 41A, an intermediate conductive layer 42A, and an upper conductive layer 43A that are sequentially stacked.

Each of the three conductive layers 41A, 42A, and 43A may include, e.g., at least one of an impurity-doped semiconductor material, a conductive silicide compound, a conductive metal nitride, a metal, or a metal alloy. For example, the lower conductive layer 41A may include a doped semiconductor material (e.g., doped polysilicon or the like), the intermediate conductive layer 42A may include at least one of a conductive silicide compound or a conductive metal nitride, and the upper conductive layer 43A may include at least one of a metal or a metal alloy.

The direct contact DC may electrically connect the cell conductive line CL and the substrate 10. The direct contact DC may be provided at a point at which the cell conductive line CL intersects a center point on the active region 12A of the long island shape. The direct contact DC may be formed on the bit line connection region of the active region 12A.

Referring to FIG. 2, the direct contact DC may include a lower layer 36 and an upper layer 37. The lower layer 36 may be located in a direct contact hole DCH that exposes the active region 12A of the substrate 10 and may be in contact with the active region 12A through a bottom surface of the direct contact hole DCH, and the upper layer 37 may be in contact with a lower surface of the cell conductive line CL.

The upper layer 37 may include a metal element, e.g., W, Rh, Cu, Co, Mo, or TiN. The lower layer 36 may be a silicide or metal silicide that is a combination of the metal element of the upper layer 37 and single crystal or polycrystalline silicon, and may reduce contact resistance between the upper layer 37 and the active region 12A. When the direct contact DC includes the upper layer 37 formed of a metal and the lower layer 36 formed of a silicide rather than polysilicon, it is possible to reduce necking-and-cut defects due to a narrow area, reduce contact resistance, and reduce void or the like occurring in polysilicon in a subsequent process.

The cell line capping layer CLC may include, e.g., at least one of silicon nitride, silicon oxynitride, silicon carbonitride, or silicon oxycarbonitride. As illustrated in FIG. 2, the cell line capping layer CLC may have a three-layer structure. For example, the cell line capping layer CLC may include a cell line capping 44A, a cell line insulating layer 45A, and a mask layer 47A. The cell line capping 44A, the cell line insulating layer 45A, and the mask layer 47A may include, e.g., at least one of silicon nitride, silicon oxynitride, silicon carbonitride or silicon oxycarbonitride.

For example, as illustrated in FIGS. 2 to 5, the cell line capping layer CLC may be a three-layer structure. In another example, the cell line capping layer CLC may have a structure of a single layer, two layers, or four or more layers. The mask layer 47A and the cell line insulating layer 45A of the cell line capping layer CLC may increase the height of the cell line structure CS to support the landing pad LP while separating the landing pad LP and the cell conductive line CL from each other.

Cell insulating films 31, 32, and 33 may be formed on the substrate 10 and the isolation layer 14A. In detail, the cell insulating films 31, 32, and 33 may be provided on a region of the substrate 10 on which the direct contact DC and the buried contact BC are not present (e.g., in regions not vertically overlapping the direct contact DC and the buried contact BC). The cell insulating films 31, 32, and 33 may be located in a third direction (a z-axis direction) between the substrate 10 and the cell conductive line CL and between the isolation layer 14A and the cell conductive line CL (e.g., in regions vertically overlapping the isolation layer 14A and a portion of the cell area separation layer 14C). The cell insulating films 31, 32, and 33 may be single films or multi-films including the first insulating film 31, the second insulating film 32, and the third insulating film 33.

For example, the first insulating film 31 may include a silicon oxide film, the second insulating film 32 may include a metal oxide film, and the third insulating film 33 may include a silicon nitride film. For example, the first and third insulating films 31 and 33 including the silicon oxide film and the silicon nitride film may have a two-layer structure.

A cell line spacer 50 may be provided on sidewalls of the cell line structure CS and the direct contact DC. The cell line spacer 50 may extend to an upper surface of the first insulating film 31 outside the direct contact hole DCH while filling the direct contact hole DCH around the direct contact DC. The cell line spacer 50 according to an embodiment of the present disclosure may include two or more types of spacers. The spacers may include, e.g., at least one of silicon oxide, silicon nitride, silicon oxynitride (SiON), silicon oxycarbonitride (SiOCN), air, or a combination thereof. Referring to FIG. 2, the cell line spacer 50 may include first to fourth spacers 51, 52, 53, and 54.

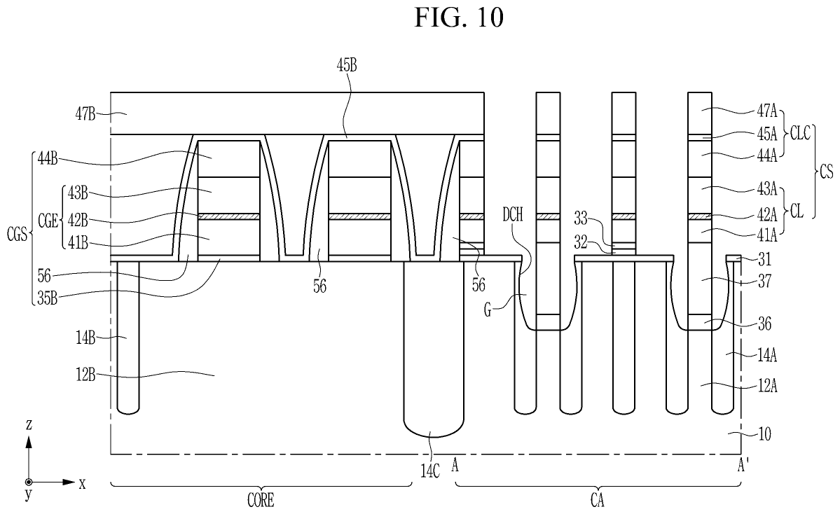

As illustrated in FIG. 2, the first spacer 51 may cover both sidewalls of the cell line structure CS, portions of inner walls of the direct contact hole DCH that are not covered with the cell line structure CS (e.g., portions of the inner walls of the direct contact hole DCH forming a gap G of FIG. 10), and an upper surface of the first insulating film 31. The second spacer 52 may fill a remaining space of the direct contact hole DCH that is not filled with the first spacer 51. The third spacer 53 may be located above the second spacer 52 and cover outer sides of the first spacer 51 (inner sides thereof are in contact with the sidewalls of the cell line structure CS) covering both sidewalls of the cell line structure CS to reinforce the outer sides of the first spacer 51. The fourth spacer 54 may cover outer sides of the third spacer 53 (the inner sides thereof are in contact with the outer sides of the first spacer 51) and sides of the buried contact BC. The first, second, and fourth spacers 51, 52, and 54 may include silicon nitride, and the third spacer 53 may include silicon oxide or air.

Referring to FIG. 3, a partition wall 48A may be provided on the substrate 10 and the isolation layer 14A. In an embodiment of the present disclosure, the partition wall 48A may overlap the cell gate structure GS formed on the substrate 10 and the isolation layer 14A. The partition wall 48A may be located between the cell line structures CS extending in the second direction (the y-axis direction). The partition wall 48A may include, e.g., at least one of silicon oxide, silicon nitride, silicon oxynitride, or a combination thereof.

At least a portion of the buried contact BC may be buried in the substrate 10. That is, a lower surface of the buried contact BC may be lower than the upper surface of the substrate 10. As shown in FIG. 2, an upper surface of the buried contact BC may be higher than that of the substrate 10.

The buried contact BC may be located between adjacent cell conductive lines CL in the first direction (the x-axis direction). The buried contact BC may be located between adjacent partition walls 48A in the second direction (the y-axis direction). The buried contact BC may overlap the substrate 10 and the isolation layer 14A between adjacent cell conductive lines CL. The buried contact BC may be connected to the storage element connection region of the active region 12A.

The buried contact BC may include, e.g., at least one of an impurity-doped semiconductor material, a conductive silicide compound, a conductive metal nitride, or a metal. The buried contact BC may include an impurity-doped semiconductor material, e.g., doped polysilicon. The buried contact BC may include, e.g., polysilicon doped with phosphorus, arsenic, boron, or a combination thereof.

Cell spacers 58 may cover outer sides of the cell line spacers 50 on both sidewalls of the cell line structure CS and a sidewall of the partition wall 48A in contact with the landing pad LP. Referring to FIG. 2, in some embodiments, when a buried contact hole is formed to accommodate the buried contact BC, an upper part of the cell line spacer 50 may be removed, resulting in a reduction of the height thereof, so the cell spacer 58 may cover the upper part of the cell line spacer 50.

A plurality of landing pads LP may be formed on buried contacts BC

corresponding thereto. Each of the landing pads LP may be electrically connected to one of the buried contacts BC and connected to the storage element connection area of the active region 12A. The landing pad LP may overlap a portion of the upper surface of the cell line structure CS.

Referring to FIG. 2, each of the landing pads LP may include a conductive barrier layer 64A and a conductive layer 66A. The conductive barrier layer 64A may be, e.g., a stacked structure of Ti, TiN, or Ti/TiN. The conductive layer 66A may include, e.g., at least one of an impurity-doped semiconductor material, a conductive silicide compound, a conductive metal nitride, a conductive metal carbide, a metal or a metal alloy.

A pad separation insulating layer 70 may be provided between a plurality of landing pads LP isolated from each other, and may contact parts of the cell line structure CS and the cell line spacer 50. An upper surface of the landing pad LP may be covered with or may not be covered with the pad separation insulating layer 70. For example, the upper surface of the landing pad LP may be at the same height as the pad separation insulating layer 70 with respect to the upper surface of the substrate 10.

The pad separation insulating layer 70 may include an insulating material and electrically disconnect the plurality of landing pads LP from each other. For example, the pad separation insulating layer 70 may include at least one of silicon oxide, silicon nitride, silicon oxynitride, silicon oxycarbonitride, or silicon carbonitride.

Referring to FIG. 2, a core gate structure CGS may be provided on the substrate 10 in the core area CORE. The core gate structure CGS may be located on the active region 12B defined by the isolation layer 14B.

The core gate structure CGS may include a core gate dielectric layer 35B, a core gate electrode CGE, and a core gate capping 44B that are sequentially stacked on the substrate 10. The core gate structure CGS may further include core gate spacers 56 on sidewalls of the core gate electrode CGE and sidewalls of the core gate capping 44B.

The core gate electrode CGE may be a single layer or may include multiple layers. FIGS. 2, 4, and 5 illustrate an example in which the core gate electrode CGE includes a lower conductive layer 41B, an intermediate conductive layer 42B, and an upper conductive layer 43B that are sequentially stacked on the core gate dielectric layer 35B. For example, two core gate structures CGS may be provided between adjacent isolation layers 14B.

An insulating liner 45B may be provided on the substrate 10. The insulating liner 45B may be formed according to a curvature of the core gate structure CGS. The insulating liner 45B may be disposed on the core gate capping 44B and the cell area separation layer 14C. The core gate spacers 56 may be disposed to cover side surfaces of the first and second insulating films 31 and 32, the core gate dielectric layer 35B, the three conductive layers 41B, 42B, and 43B, and the core gate capping 44B.

The insulating liner 45B may be disposed on the core gate spacers 56. The insulating liner 45B may include, e.g., at least one of silicon nitride, silicon oxynitride, silicon carbonitride, or silicon oxycarbonitride.

A buried insulating layer 46 may be formed between the plurality of core gate structures CGS. According to some embodiments, the buried insulating layer 46 may be provided on the insulating liner 45B when the insulating liner 45B is formed. The buried insulating layer 46 may also be formed on the cell area separation layer 14C.

The buried insulating layer 46 may include an insulating material having excellent gap fill characteristics. The buried insulating layer 46 may be formed of, e.g., a boron-phosphorous silicate glass (BPSG) film, a high-density plasma (HDP) oxide film, an O₃-TEOS film, undoped silicate glass (USG) or a Tonen SilaZene (TOSZ) material. In an embodiment of the present disclosure, the buried insulating layer 46 may include silicon oxide formed of the TOSZ material.

For example, an upper surface of the buried insulating layer 46 may be level with the insulating liner 45B extending along the upper surface of the core gate structure CGS. According to some embodiments, when the insulating liner 45B is not provided, the upper surface of the buried insulating layer 46 may be level with the upper surface of the core gate structure CGS.

A mask layer 47B may be provided on the core gate structure CGS and the buried insulating layer 46. In some embodiments, when the insulating liner 45B is provided, the mask layer 47B may cover the insulating liner 45B and the buried insulating layer 46 that extend along the upper surface of the core gate structure CGS. A height of the upper surface of the mask layer 47B may be the same as that of the upper surface of the cell line capping layer CLC, e.g., with respect to the upper surface of the substrate 10.

In embodiments, the mask layer 47B may include a material different from that of the buried insulating layer 46. For example, when the buried insulating layer 46 includes silicon oxide, the mask layer 47B may include at least one of silicon nitride, silicon oxynitride, silicon carbonitride, and silicon oxycarbonitride.

Contact plugs CP may be provided at both sides of the core gate structure CGS. The contact plugs CP may extend to the active region 12B in the substrate 10 while passing through the mask layer 47B and the buried insulating layer 46. An interconnection line may be provided on the mask layer 47B. The contact plug CP and the interconnection line may be separated from each other by an interconnection separation recess. In an embodiment of the present disclosure, the contact plug CP may be formed simultaneously with the landing pad LP and thus may include the same material as the landing pad LP.

For example, the contact plug CP may include a conductive barrier layer 64B and a conductive layer 66B. The conductive barrier layer 64B may be formed simultaneously with the conductive barrier layer 64A of the landing pad LP and thus may include the same material as the conductive barrier layer 64A, and the conductive layer 66B may be formed simultaneously with the conductive layer 66A of the landing pad LP and thus include the same material as the conductive layer 66A.

Referring to FIG. 2, the contact plug CP may be accommodated in a contact plug hole. Most of the sidewalls of the contact plug hole may be covered with contact plug spacers 59 but an inner wall located in the substrate 10 among inner walls of the contact plug hole may be covered with a metal silicide layer 62B. Therefore, the conductive barrier layer 64B of the contact plug CP may be in contact with the metal silicide layer 62B in the substrate 10 to be electrically connected to the active region 12B in the substrate 10, and may be insulated from the outside of the substrate 10 due to the contact plug spacers 59.

The metal silicide layer 62B may be formed of a metal (e.g., cobalt, titanium, or nickel) that reacts with silicon to form silicide, and the contact plug spacers 59 may include, e.g., at least one of silicon nitride, silicon oxynitride, silicon carbonitride or silicon carbonitride.

For example, the contact plug spacer 59 may be applied to all the contact plugs CP of the core area CORE. In another example, the contact plug spacers 59 may be provided only on the sidewalls of some of the contact plugs CP in the core area CORE.

The contact plug spacers 59 may increase a distance between the contact plug CP and the core gate structure CGS and thus be particularly useful for highly scaled semiconductor devices. In addition, a contact plug hole for forming the contact plug CP may be formed to be larger than a desired size, and the size thereof may be controlled using the contact plug spacers 59. Accordingly, an aspect ratio of the contact plug hole to be patterned may be reduced, thus reducing a burden on a patterning process.

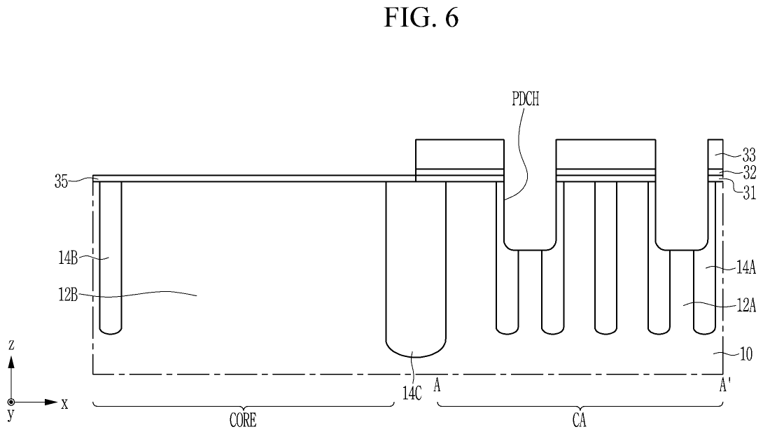

Next, a manufacturing method of a semiconductor device according to an embodiment of the present disclosure will be described in detail with reference to FIGS. 6 to 10. FIGS. 6 to 10 are cross-sectional views of stages in a manufacturing process of the semiconductor device of FIG. 2.

Some components to be formed in the cell array area CA may be formed simultaneously with some components to be formed in the core area CORE.

Referring to FIG. 6, the isolation layers 14A and 14B and the cell area separation layer 14C may be formed on the substrate 10. The isolation layers 14A and 14B and the cell area separation layer 14C may be formed by a shallow trench isolation (STI) process.

The cell array area CA and the core area CORE that are separated from each other by the cell area separation layer 14C may be formed on the substrate 10. A plurality of the active regions 12A and 12B that are defined by the isolation layers 14A and 14B may be formed in the cell array area CA and the core area CORE,

According to some embodiments, in a manufacturing method of a semiconductor device including word lines WL of a buried type (see FIG. 1), the word lines WL of the buried type may be formed in the substrate 10 before forming bit lines BL (see FIG. 1).

According to some embodiments, a plurality of cell gate trenches T1 (see FIG. 3) may be formed in the cell array area CA of the substrate 10 to manufacture the cell gate structure GS (see FIGS. 3 to 5) including the word lines WL of the buried type. The plurality of cell gate trenches T1 may extend parallel to each other in the first direction (the x-axis direction), and each may have a line shape crossing the plurality of active regions 12A. The cell gate insulating layer 22 (see FIGS. 3 to 5), the cell gate electrode 24 (see FIGS. 3 to 5), and the cell gate capping 26 (see FIGS. 3 to 5) may be sequentially formed in the cell gate trenches T1. The cell gate electrode 24 may correspond to the word lines WL as described above. In some embodiments, a cell gate capping conductive layer may be additionally formed between the cell gate electrode 24 and the cell gate capping 26. An upper surface of the cell gate capping 26 may be located at approximately the same level as that of the substrate 10.

In an embodiment of the present disclosure, after the cell gate structure GS is formed, impurity ions may be injected into both regions outside the cell gate structure GS to form a source/drain region having a certain depth from the upper surfaces of the active regions 12A. According to another embodiment of the present disclosure, an impurity ion injection process may be performed to form the source/drain region before the cell gate structure GS is formed.

Next, the first insulating film 31, the second insulating film 32, and the third insulating film 33 may be sequentially formed in the cell array area CA and the core area CORE of the substrate 10, and thereafter the first insulating film 31, the second insulating film 32, and the third insulating film 33 may be removed from the core area CORE to expose the active regions 12B of the substrate 10. Thereafter, the gate dielectric film 35 may be formed on the core area CORE of the substrate 10 while the cell array area CA is covered with a mask layer. FIG. 6 illustrates that sidewalls of the first to third insulating films 31, 32, and 33 are in contact with sidewalls of the gate dielectric film 35 at a midpoint on the cell area separation layer 14C, but the first to third insulating films 31, 32, and 33 and the gate dielectric film 35 may be formed to not overlap each other or not to be in contact with each other on the cell area separation layer 14C. The first insulating film 31 may be an oxide film, the second insulating film 32 may be a metal oxide film, and the third insulating film 33 may be a nitride film.

The gate dielectric film 35 may include at least one selected from a silicon oxide film, a silicon nitride film, a silicon oxynitride film, an oxide/nitride/oxide (ONO) film, or a high-k dielectric film having a higher dielectric constant than the silicon oxide film. For example, the gate dielectric film 35 may have a dielectric constant of about 10 to 25. In an embodiment of the present disclosure, the gate dielectric film 35 may include at least one of hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). For example, the gate dielectric film 35 may include at least one of HfO₂, Al₂O₃, HfAlO₃, Ta₂O₃, and TiO₂.

Thereafter, the first to third insulating films 31, 32, and 33 and the substrate 10 in the cell array area CA may be etched to form a pre-direct contact hole PDCH. A bottom surface of the pre-direct contact hole PDCH includes, e.g., exposes, a part of the active region 12A.

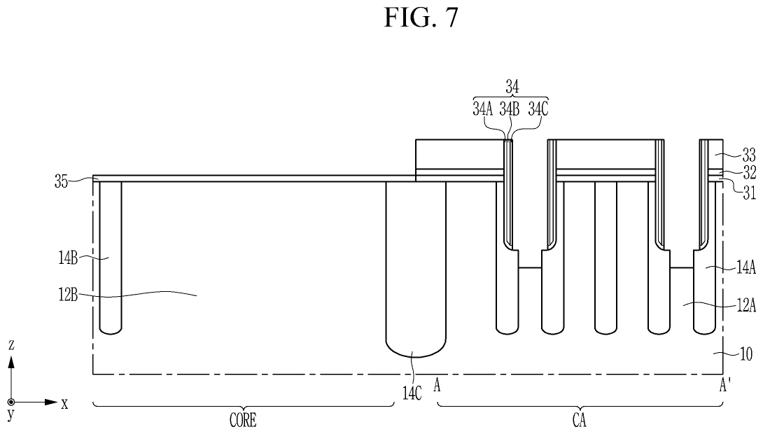

Thereafter, referring to FIG. 7, charging spacers 34 may be formed on sidewalls of the pre-direct contact hole PDCH. According to an embodiment of the present disclosure, the charging spacers 34 may include three charging insulating films 34A, 34B, and 34C, the intermediate charging insulating film 34B may include silicon oxide, and the other two charging insulating films 34A and 34C may include silicon nitrides. The charging spacers 34 may protect sidewalls of the pre-direct contact hole PDCH, and particularly, sidewalls of the substrate 10 in a subsequent process.

The exposed part of the active region 12A at the bottom of the pre-direct contact hole PDCH may be dented, e.g., recessed, to a certain degree during the formation of the charging spacers 34.

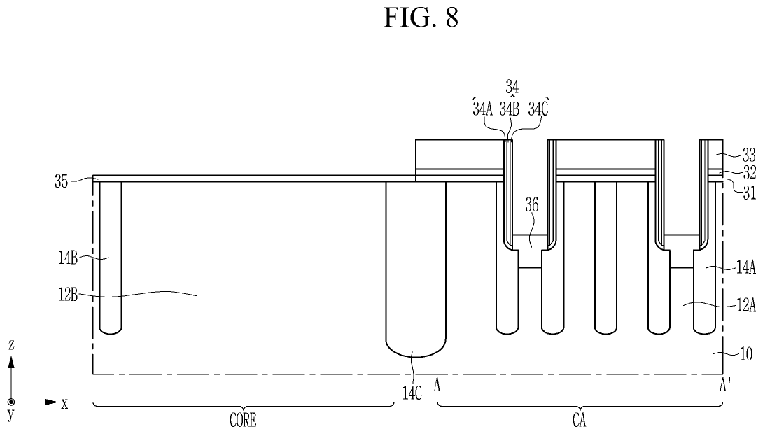

Referring to FIG. 8, a part of the active region 12A exposed through the pre-direct contact hole PDCH may be grown or polysilicon having a high impurity concentration may be stacked and etched to form a lower layer 36 of a direct contact DC.

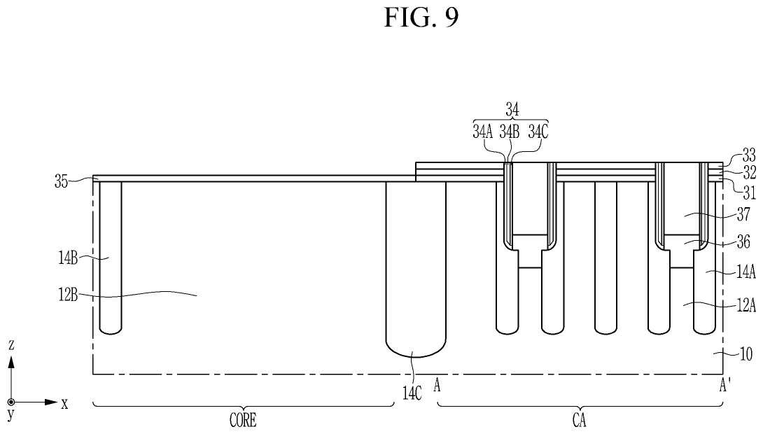

Next, referring to FIG. 9, a metal or the like may be stacked and etched to form the upper layer 37 of the direct contact DC. In this case, at least a portion of the lower layer 36 is converted into a silicide by causing a metal element of the upper layer 37 to permeate the single crystal silicon or polysilicon of the lower layer 36 by appropriately performing heat treatment or the like. When the direct contact DC includes the upper layer 37 formed of metal and the lower layer 36 formed of silicide (rather than polysilicon), it is possible to reduce necking-and-cut defects due to a narrow area, reduce contact resistance, and reduce void or the like occurring in polysilicon in a subsequent process.

Thereafter, referring to FIG. 10, a lower conductive layer, an intermediate conductive layer, an upper conductive layer, and a capping layer may be sequentially stacked on the third insulating film 33 and the gate dielectric film 35. The three conductive layers may include a metal or the like. The capping layer may include, e.g., at least one of silicon nitride, silicon oxynitride, silicon carbonitride, or silicon oxycarbonitride.

The gate dielectric film 35, the lower conductive layer, the intermediate conductive layer, the upper conductive layer, and the capping layer in the core area CORE may be patterned while the cell array area CA is covered with a mask layer. As a result, the core gate electrode CGE in which the lower conductive layer 41B, the intermediate conductive layer 42B, and the upper conductive layer 43B are stacked is formed on the core gate dielectric layer 35B. The core gate capping 44B may be provided on the core gate electrode CGE. The core gate spacers 56 may be formed on both sidewalls of a stacked structure of the core gate dielectric layer 35B, the core gate electrode CGE, and the core gate capping 44B.

The core gate spacers 56 may include, e.g., an oxide, a nitride, or a combination thereof. The core gate spacers 56 may be formed on etched sidewalls of the first and second insulating films 31 and 32, the three conductive layers, and the capping layer on the cell area separation layer 14C, as well as both sidewalls of the stacked structure of the core gate dielectric layer 35B, the core gate electrode CGE, and the core gate capping 44B on the core area CORE.

Thereafter, an insulating layer may be formed on entire surfaces of the core area CORE and the cell array area CA. The insulating layer may include, e.g., at least one of silicon nitride, silicon oxynitride, silicon carbonitride, or silicon oxycarbonitride.

A space between an upper surface of the insulating layer and the core gate structure CGS may be filled with a buried insulating layer 46. The buried insulating layer 46 may be formed of an insulating material having excellent gap fill characteristics.

The buried insulating layer 46 may be formed of, e.g., a boron-phosphorous silicate glass (BPSG) film, a high-density plasma (HDP) oxide film, an O₃-TEOS film, undoped silicate glass (USG) or a Tonen SilaZene (TOSZ) material. In addition, the buried insulating layer 46 may be formed by at least one of thin-film forming techniques for providing excellent step coverage. For example, the buried insulating layer 46 may be formed by performing a deposition method, e.g., chemical vapor deposition (CVD), subatmospheric CVD (SACVD), low-pressure CVD (LPCVD), plasma enhanced CVD (PECVD), or physical vapor deposition (PVD).

In embodiments, the buried insulating layer 46 may be formed using Tonen Silazane (TOSZ). The TOSZ film may be a polysilazane film. The TOSZ film may be formed by a spin coating method, and may be formed by supplying O₂ and H₂O after performing spin coating and performing an annealing process to remove ammonia and hydrogen from the TOSZ film. Thus, the TOSZ film may be a silicon oxide film.

Thereafter, an upper surface of the buried insulating layer 46 may be planarized by a planarization process. Accordingly, the upper surface of the buried insulating layer 46 may be level with that of the insulating layer.

Next, an insulating layer is formed on the insulating layer and the buried insulating layer 46, and patterned by a photolithography process to form the mask layer 47B and the insulating liner 45B on the core area CORE while forming a plurality of mask layers 47A and a plurality of cell line insulating layers 45A in the cell array area CA. According to an embodiment of the present disclosure, the mask layer may not be etched in the core area CORE to remain.

In embodiments, the mask layers 47A and 47B may include a material different from that of the buried insulating layer 46. For example, when the buried insulating layer 46 includes silicon oxide, the mask layers 47A and 47B may include at least one of silicon nitride, silicon oxynitride, silicon carbonitride, or silicon oxycarbonitride.

Thereafter, a cell line structure CS, the direct contact DC, and a direct contact hole DCH may be formed in the cell array area CA by etching the capping layer, the three conductive layers, the upper layer 37 and the lower layer 36 of the direct contact DC, the charging spacers 34, and the second and third insulating films 32 and 33 by using, as an etching mask, the mask layers 47A and 47B, the cell line insulating layer 45A, and an insulating liner 45B, which are located below the capping layer 44, the three conductive layers 41, 42, and 43, the upper layer 37 and the lower layer 36 of the direct contact DC, the charging spacers 34, and the second and third insulating films 32 and 33.

According to an embodiment of the present disclosure, the etch selectivity of the upper layer 37, which is formed of a metal, and of the lower layer 36, which is formed of silicide, of the direct contact DC with respect to the silicon active region 12A may be increased by dry etching using Cl₂/N₂-based O₂ plasma. For example, the type of etching gas to be used may vary according to a depth of etching. The Cl₂/N₂ gas may be used an initial etching stage, Cl₂/N₂+2O₂ gas may be used at a middle etching stage, and Cl₂/N₂+SO₂ gas may be used at a last etching stage.

Although the third insulating film 33 may be partially removed during the etching of the upper layer 37 and the lower layer 36 of the direct contact DC, the second insulating film 32 formed of a metal oxide having high etch selectivity with respect to a metal is not removed and thus films below the second insulating film 32 may not be also removed.

The cell line structure CS may include the cell conductive line CL and the cell line capping layer CLC on the cell conductive line CL, the cell conductive line CL may include the lower conductive layer 41A, the intermediate conductive layer 42A, and the upper conductive layer 43A, and the cell line capping layer CLC may include the cell line capping 44A, the cell line insulating layer 45A, and the mask layer 47A.

The cell conductive line CL may be connected to the active region 12A of the substrate 10 through the direct contact DC. When the cell conductive line CL includes three conductive layers 41A, 42A, and 43A, the lower conductive layer 41A may extend to the inside of the direct contact hole DCH to be in contact with the upper layer 37 of the direct contact DC.

Because a width of the direct contact DC is less than a diameter of the direct contact hole DCH, there may be an empty space, i.e., a gap G, of the direct contact hole DCH that is not filled with the direct contact DC. Because the cell conductive line CL extends long in the y-axis direction, the direct contact DC may not be entirely surrounded by one gap G but there may be a pair of separated gaps G outside both sidewalls of the direct contact DC, i.e., at opposite sides with respect to the direct contact DC. That is, there may be one direct contact DC and the pair of gaps G in the direct contact DCH, and the pair of gaps G may be separated from each other by the direct contact DC.

Referring to FIG. 2, structures, e.g., the first to fourth spacers 51, 52, 53 and 54, the landing pad LP, and the pad separation insulating layer 70, may be formed, thereby completing the manufacture of a semiconductor device according to an embodiment of the present disclosure.

By way of summation and review, embodiments relate to a semiconductor device with reduced defects and improved performance. That is, according to embodiments, defects in the semiconductor device may be reduced by forming a direct contact to include an upper layer formed of a metal and a lower layer formed of silicide rather than polysilicon, thereby reducing necking-and-cut defects due to a narrow area, reducing contact resistance, and reducing voids occurring in polysilicon.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor memory device, comprising:
a substrate including a cell array area and a core area near the cell array area, the cell array area including a direct contact hole exposing an active region;
a buried contact in the cell array area, the buried contact being connected to a storage element;
a direct contact in the cell array area, the direct contact including an upper layer and a lower layer, the upper layer including a metal, and the lower layer being in the direct contact hole in direct contact with the active region and including a silicide of the metal;
bit lines in contact with the upper layer of the direct contact; and
word lines crossing the bit lines.

2. The semiconductor memory device as claimed in claim 1, wherein the upper layer includes at least one of W, Rh, Cu, Co, Mo, and TiN.

3. The semiconductor memory device as claimed in claim 2, wherein the upper layer includes TiN.

4. The semiconductor memory device as claimed in claim 1, further comprising a cell insulating film on the substrate, the cell insulating film not overlapping the buried contact and the direct contact.

5. The semiconductor memory device as claimed in claim 4, wherein the cell insulating film has a three-layer structure.

6. The semiconductor memory device as claimed in claim 5, wherein:
the cell insulating film includes a first insulating film, a second insulating film, and a third insulating film that are sequentially stacked,
the first insulating film includes a semiconductor oxide film,
the second insulating film includes a metal oxide film, and
the third insulating film includes a semiconductor nitride film.

7. A manufacturing method of a semiconductor memory device, the method comprising:
stacking a cell insulating film on a cell array area of a substrate;
forming a direct contact hole by etching the cell insulating film, such that the direct contact hole exposes an active region of the substrate;
forming a lower layer in the direct contact hole, such that the lower layer includes a semiconductor in contact with the active region through the direct contact hole;
forming an upper layer on the lower layer, the upper layer including a metal;
converting at least a portion of the lower layer into a silicide of the metal;
forming bit lines on the upper layer; and
forming a direct contact by etching the upper layer and the lower layer by using the bit lines as a mask.

8. The manufacturing method as claimed in claim 7, wherein the upper layer and the lower layer are etched by a dry etching method.

9. The manufacturing method as claimed in claim 8, wherein the upper layer and the lower layer are etched by Cl₂/N₂-based O₂ plasma.

10. The manufacturing method as claimed in claim 9, wherein etching the upper layer and the lower layer includes varying an etching gas according to a depth of etching.

11. The manufacturing method as claimed in claim 10, wherein etching the upper layer and the lower layer includes using Cl₂/N₂ gas at an initial etching stage, using Cl₂/N₂+2O₂ gas at a middle etching stage, and using Cl₂/N₂+SO₂ gas at a last etching stage.

12. The manufacturing method as claimed in claim 7, wherein the upper layer is formed of at least one of W, Rh, Cu, Co, Mo, and TiN.

13. The manufacturing method as claimed in claim 12, wherein the upper layer formed of TiN.

14. The manufacturing method as claimed in claim 7, wherein the cell insulating film is formed to have a three-layer structure.

15. The manufacturing method as claimed in claim 14, wherein:
the cell insulating film is formed to include a first insulating film, a second insulating film, and a third insulating film that are sequentially stacked,
the first insulating film is formed of a semiconductor oxide film,
the second insulating film is formed of a metal oxide film, and
the third insulating film is formed of a semiconductor nitride film.

16. The manufacturing method as claimed in claim 15, further comprising etching the second insulating film and the third insulating film after the forming the bit lines.

17. The manufacturing method as claimed in claim 7, wherein forming the lower layer includes growing the active region.

18. The manufacturing method as claimed in claim 7, wherein forming the lower layer includes stacking a semiconductor on the active region and etching the semiconductor.

19. The manufacturing method as claimed in claim 18, wherein forming the lower layer includes stacking polysilicon on the active region and etching the polysilicon.

20. The manufacturing method as claimed in claim 19, wherein forming the lower layer includes stacking high impurity concentration polysilicon on the active region and etching the high impurity concentration polysilicon.
